(19) United States
(12) Patent Application Publication
(10) Pub. No.: US 2020/0343184 A1
(43) Pub. Date: Oct. 29, 2020

(54) SEMICONDUCTOR PACKAGE AND MANUFACTURING METHOD THEREOF

(71) Applicant: Powertech Technology Inc., Hsinchu County (TW)

(72) Inventors: Hiroyuki Fujishima, Hsinchu County (TW); Hung-Hsin Hsu, Hsinchu County (TW); Shang-Yu Chang Chien, Hsinchu County (TW); Nan-Chun Lin, Hsinchu County (TW)

(73) Assignee: Powertech Technology Inc., Hsinchu County (TW)

(21) Appl. No.: 16/392,559

(22) Filed: Apr. 23, 2019

(51) Int. Cl. H01L 23/528; H01L 23/48; H01L 23/522; H01L 23/31; H01L 25/065; H01L 21/768; H01L 21/56; H01L 23/00

(52) U.S. Cl. CPC H01L 23/5283; H01L 23/481; H01L 23/5226; H01L 23/3128; H01L 25/0657; H01L 21/76898; H01L 2224/0401; H01L 24/09; H01L 24/17; H01L 2224/02379; H01L 2224/02381; H01L 2224/02373; H01L 2224/0231; H01L 21/563

(57) ABSTRACT

A semiconductor package including a die stack, an insulating encapsulation encapsulating the die stack, a first redistribution layer (RDL) and a second RDL disposed on two opposite sides of the insulating encapsulation, and a through insulating via disposed aside the die stack and extending through the insulating encapsulation to be electrically connected to the first RDL and the second RDL. The die stack includes a first die and a second die stacked upon one another and electrically connected to the first die. The second die includes a through semiconductor via disposed therein. One of the first die and the second die includes conductive features having different thicknesses. The second RDL is connected to the through semiconductor via of the second die. A manufacturing method of a semiconductor package is also provided.

### BACKGROUND OF THE INVENTION

### 1. Field of the Invention

The present invention generally relates to a package structure and a manufacturing method thereof, and more particularly, to a semiconductor package including a through insulating via and/or a through semiconductor via, and a manufacturing method thereof.

### 2. Description of Related Art

In recently years, electronic apparatus are more important for human's life. In order for electronic apparatus design to achieve being light, slim, short, and small, semiconductor packaging technology has kept progressing, in attempt to develop products that are smaller in volume, lighter in weight, higher in integration, and more competitive in market. Since the chip package technique is highly influenced by the development of integrated circuits, therefore, as the size of electronics has become demanding, so does the package technique. As such, miniaturizing the semiconductor package while maintaining the process simplicity has become a challenge to researchers in the field.

### SUMMARY OF THE INVENTION

The disclosure provides a semiconductor package and a manufacturing method thereof, which is helpful to miniaturization design and manufacturing cost.

The disclosure provides a semiconductor package including a die stack, an insulating encapsulation encapsulating the die stack, a first redistribution layer (RDL) and a second RDL disposed on two opposite sides of the insulating encapsulation, and a through insulating via disposed aside the die stack and extending through the insulating encapsulation to be electrically connected to the first RDL and the second RDL. The die stack includes a first die and a second die stacked upon one another and electrically connected to the first die. The second die includes a through semiconductor via (TSV) disposed therein. One of the first die and the second die includes conductive features having different thicknesses. The second RDL is connected to the TSV of the second die.

The disclosure provides a manufacturing method of a semiconductor package. The method includes at least the following steps. A die stack is disposed on a first RDL, where the die stack includes a first die and a second die stacked upon one another, the second die includes a TSV disposed therein, and one of the first die and the second die includes conductive features having different thicknesses. An insulating encapsulation is formed on the first RDL to encapsulate the die stack. A TIV is formed on the first RDL, where the TIV is laterally encapsulated by the insulating encapsulation. A second RDL is formed on the insulating encapsulation to be connected to the TIV and the TSV of the second die of the die stack.

Based on the above, the semiconductor package including the die stack may provide multi-functions in a single package to reduce the fabrication cost and the packaging volume. Moreover, since one of the first die and the second die includes TSVs, the signal transmission path between two dies is shortened so that the efficiency of the semiconductor package is improved and the integration is enhanced.

To make the above features and advantages of the present invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1H are schematic cross-sectional views illustrating a manufacturing method of a semiconductor package according to an embodiment of the disclosure.

FIG. 2 is a schematic cross-sectional view illustrating an application of a semiconductor package according to an embodiment of the disclosure.

FIG. 3A and FIG. 3E are schematic cross-sectional views illustrating a manufacturing method of a semiconductor package according to an embodiment of the disclosure.

FIG. 4 is a schematic cross-sectional view illustrating a semiconductor package according to an embodiment of the disclosure.

FIG. 5A to FIG. 5D are schematic cross-sectional views illustrating a manufacturing method of a semiconductor package according to an embodiment of the disclosure.

FIG. 6A and FIG. 6D are schematic cross-sectional views illustrating a manufacturing method of a semiconductor package according to an embodiment of the disclosure.

FIG. 7A and FIG. 7C are schematic cross-sectional views illustrating a manufacturing method of a semiconductor package according to an embodiment of the disclosure.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

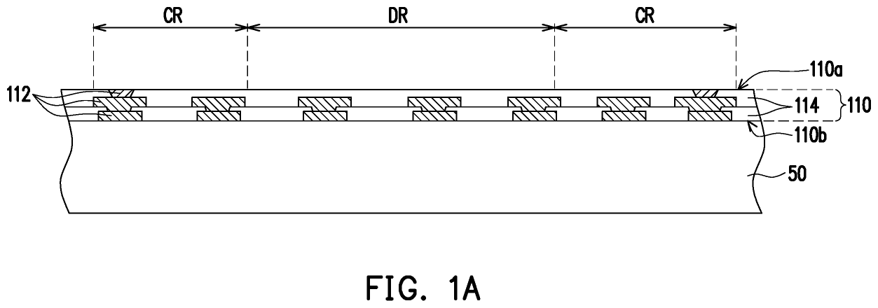

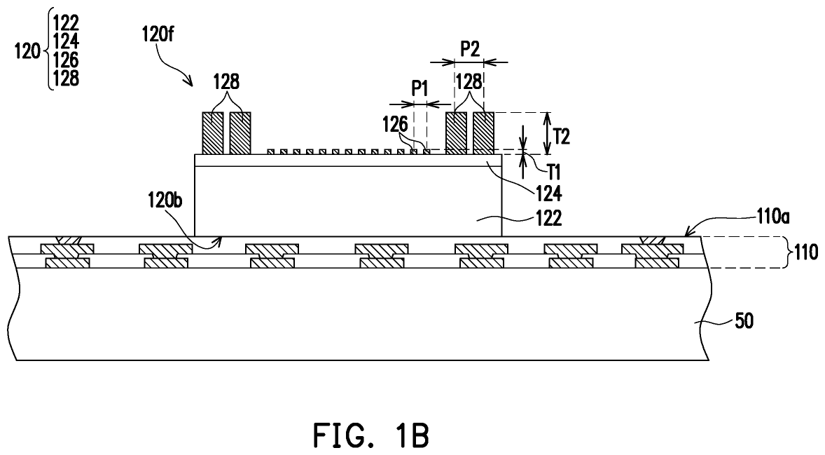

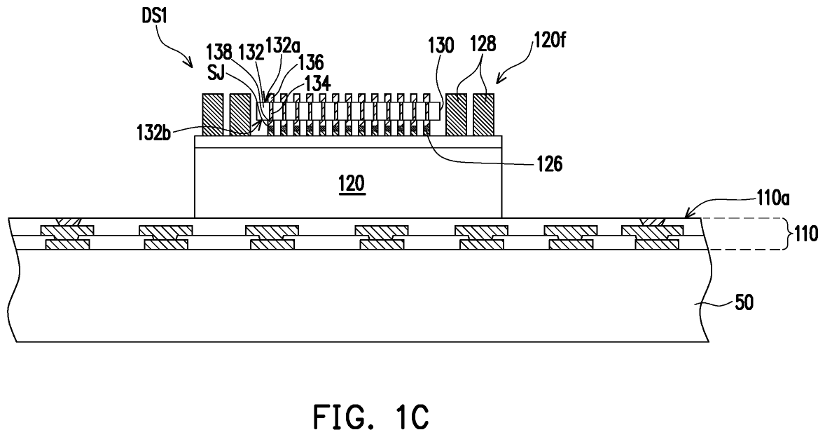

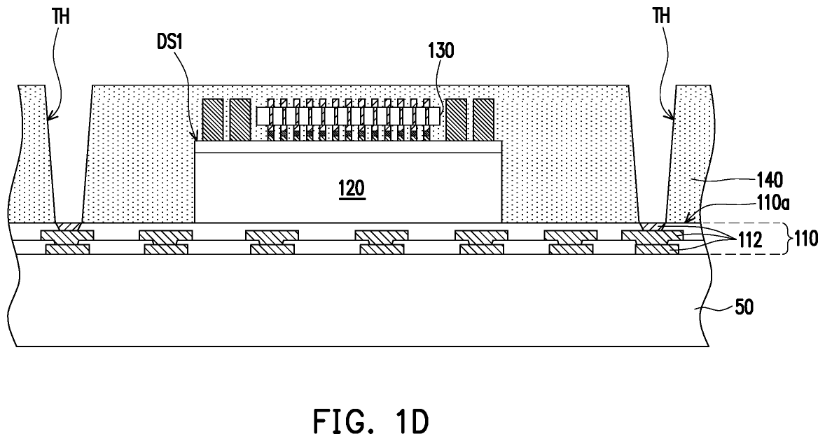

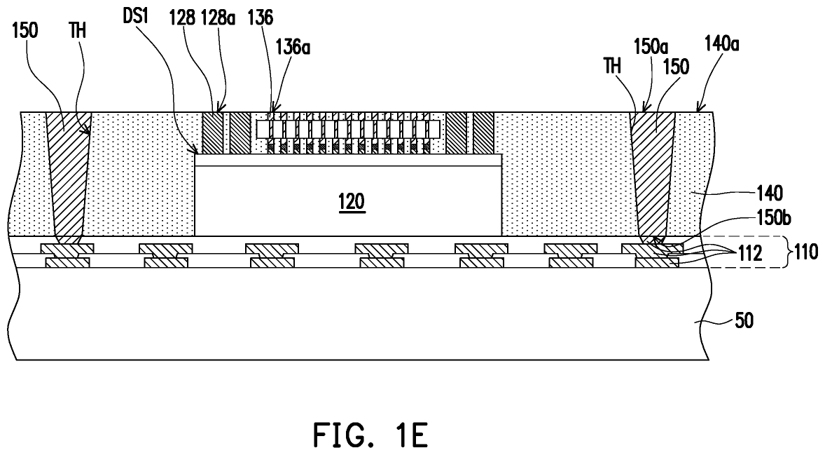

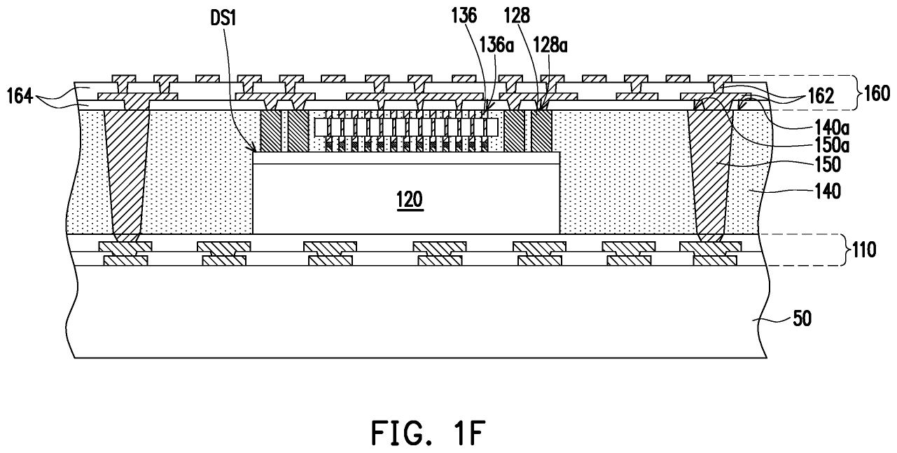

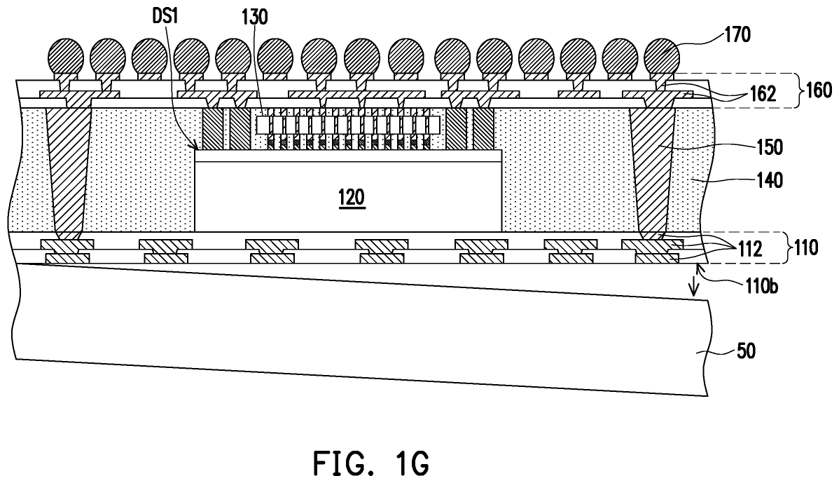

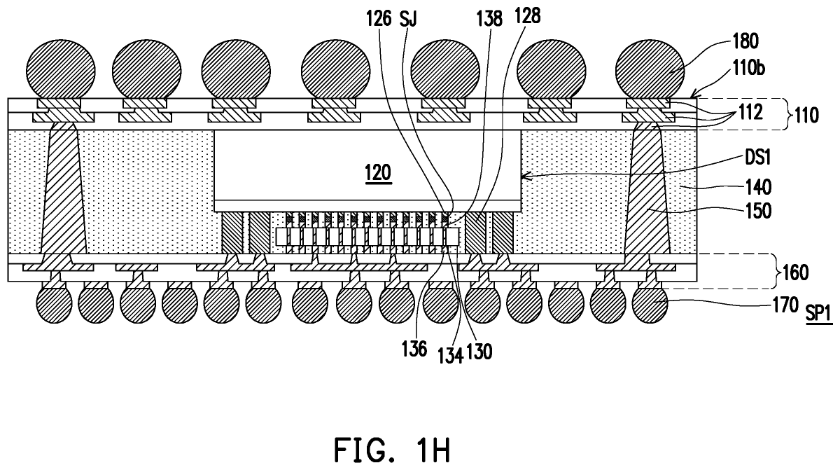

FIG. 1A to FIG. 1H are schematic cross-sectional views illustrating a manufacturing method of a semiconductor package according to an embodiment of the disclosure. Referring to FIG. 1A, a backside redistribution layer (RDL) 110 is formed on a temporary carrier 50. For example, the temporary carrier 50 may be a wafer-level or panel-level substrate made of glass, plastic, metal, or other suitable materials as long as the material is able to withstand the subsequent processes while carrying the structure formed thereon. The backside RDL 110 has a first surface 110a and a second surface 110b opposite to the first surface 110a. The second surface 110b of the backside RDL 110 may be planar and may be directly or indirectly bonded to the temporary carrier 50. In some embodiments, the temporary carrier 50 is provided with a de-conductive bonding layer (e.g., light to heat conversion (LTHC) release layer; not shown), and the backside RDL 110 is formed on the de-conductive bonding layer. The de-conductive bonding layer may enhance the releasibility of the second surface 110b of the backside RDL 110 from the temporary carrier 50 in the subsequent processes.

In some embodiments, the backside RDL 110 includes at least one patterned conductive layer 112 and at least one patterned dielectric layer 114. A Portion of the patterned conductive layer 112 may be formed on the first surface 110a and the second surface 110b and revealed by the patterned dielectric layer 114 for further electrical connection. The other portion of the patterned conductive layer 112 may be embedded in the patterned dielectric layer 114. The patterned conductive layer 112 includes conductive lines, conductive vias, conductive pads, etc. In some embodiments, the portion of the patterned conductive layer 112 located at the second surface 110b includes conductive pads or under-ball metallurgy (UBM) patterns for a ball mounting process. The first surface 110a of the backside RDL 110 includes a die attach region DR and a connecting region CR surrounding the die attach region DR. The portion of the patterned conductive layer 112 on the first surface 110a may be revealed and may be formed corresponding to the connecting region CR for connecting the subsequently formed through insulating vias.

For example, the manufacturing method of the backside RDL 110 includes at least the following steps. A first level of the patterned conductive layer 112 is formed on the temporary carrier 50 by forming a seed layer (not shown) on the temporary carrier 50, forming a photoresist layer with openings (not shown) on the seed layer, forming a conductive material (e.g., copper, aluminium, nickel, etc.) on the seed layer and within the openings of the photoresist layer, removing the photoresist layer, using the conductive material as a mask to remove the seed layer without covering by the conductive material, etc. Alternatively, the first level of the patterned conductive layer 112 may be formed by lamination or other suitable techniques. Next, a first level of the patterned dielectric layer 114 is formed on the temporary carrier 50 to cover the patterned conductive layer 112 using deposition, lithography and etching processes or other suitable techniques. The first level of the patterned dielectric layer 114 includes a plurality of openings exposing at least a portion of the first level of the patterned conductive layer 112 beneath. A material of the patterned dielectric layer 114 includes inorganic or organic dielectric materials such as polyimide (PI), polybenzoxazole (PBO), benezocyclobutene (BCB), or the like. In some embodiments, a second level of the patterned conductive layer 112 is formed on the first level of the patterned dielectric layer 114 and inside the openings of the first level of the patterned dielectric layer 114 to be connected to the first level of the patterned conductive layer 112. A second level of the patterned dielectric layer 114 is optionally formed on the first level of the patterned dielectric layer 114 to cover the patterned conductive layer 112 so as to form a multi-layered redistribution structure. In alternative embodiments, the patterned dielectric layer 114 is formed prior to the patterned conductive layer 112. The levels of the patterned conductive layer and the patterned dielectric layer throughout the drawings are only illustrative example. It should be noted that the numbers of the patterned conductive layer and the patterned dielectric layer and the forming sequence thereof depend on the circuit design.

Referring to FIG. 1B and FIG. 1C, a die stack DS1 including a bottom die 120 and a top die 130 stacked on and electrically connected to the bottom die 120 is disposed on the backside RDL 110. The bottom die 120 may be larger than the top die 130 so that the entirety of the top die 130 may be disposed within the area defined by the bottom die 120. The bottom die 120 and the top die 130 may be or include a logic die, a memory die, or combinations thereof. In some embodiments, the bottom die 120 includes a semiconductor substrate 122, an interconnecting layer 124 disposed on the semiconductor substrate 122, and a plurality of first and second conductive features 126 and 128 disposed on the interconnecting layer 124. The bottom die 120 has a front side 120f and a back side 120b opposite to the front side 120f. The first and second conductive features 126 and 128 may be distributed at the front side 120f, and the back side 120b faces the backside RDL 110. In some embodiments, a die attach layer (not shown) is attached onto the back side 120b of the bottom die 120 such that the bottom die 120 is bonded to the first surface 110a of the backside RDL 110 through the die attach layer.

The semiconductor substrate 122 may include a variety integrated circuits (IC) formed therein. For example, active components (e.g., transistors) and/or passive components (e.g., resistors, capacitors) may be formed in the semiconductor substrate 122 of the bottom die 120. In some embodiments, the interconnecting layer 124 includes a dielectric layer (not shown) and a circuitry (not shown) embedded in the dielectric layer. The circuitry of the interconnecting layer 124 may be electrically connected to the active components and/or passive components in the semiconductor substrate 122 and may also be electrically connected to the first and second conductive features 126 and 128. The first and second conductive features 126 and 128 may include pillars, bumps, vias, or other shapes and forms which are not limited thereto. The first conductive features 126 may be arranged as an array with fine pitches corresponding to a central region of the interconnecting layer 124 for die stacking. The second conductive features 128 may be disposed on a peripheral region of the interconnecting layer 124 surrounding the central region.

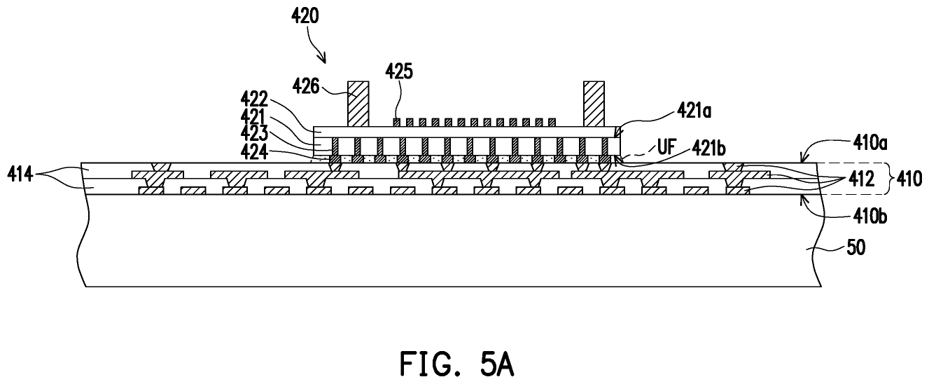

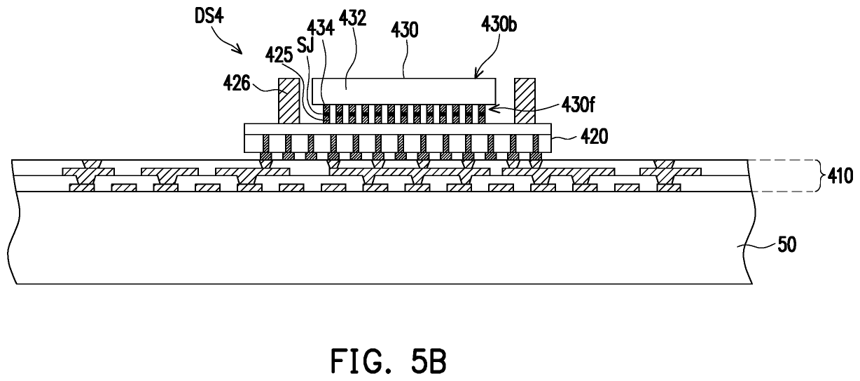

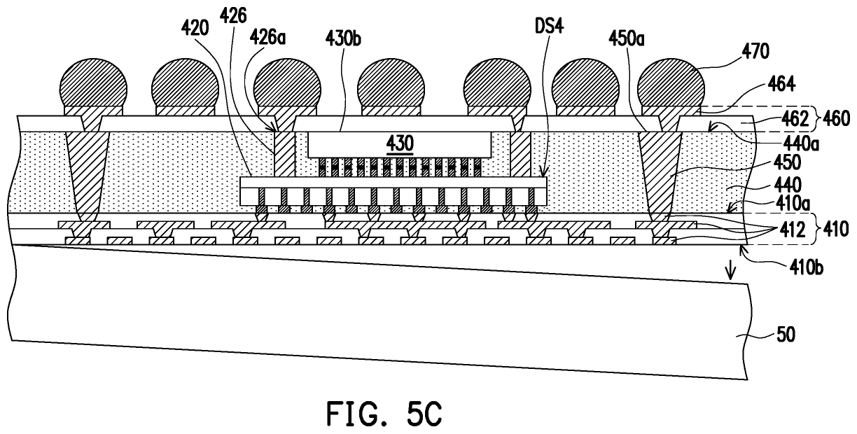

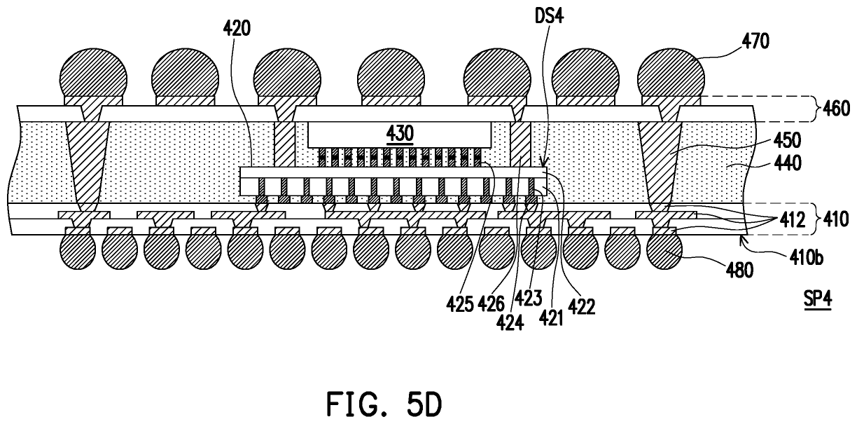

In some embodiments, a first pitch P1 between two adjacent first conductive features 126 is finer than a second pitch P2 between two adjacent second conductive features 128. It should be appreciated that although two second conductive features 128 are illustrated at each of two opposing sides of the first conductive features 126, more or less second conductive features 128 may be disposed around the first conductive features 126. In some embodiments, the first and second conductive features 126 and 128 are of different dimensions. For example, a first thickness T1 of one of the first conductive features 126 is less than a second thickness T2 of one of the second conductive features 128. In some embodiments, each of the second conductive features 128 is thicker and/or wider than each of the first conductive features 126. In alternative embodiments, the first thickness T1 of one of the first conductive features 126 is substantially equal to the second thickness T2 of one of the second conductive features 128 as will be discussed later in accompany with FIG. 5.

Continue to FIG. 1C, after disposing the bottom die 120 on the backside RDL 110, the top die 130 is stacked on the bottom die 120 using, for example, a flip-chip technique or other suitable process. In some embodiments, the second conductive features 128 are thicker than the thickness of the top die 130. In some embodiments, the top die 130 includes a semiconductor substrate 132 having a first surface 132a and a second surface 132b opposite to each other, a plurality of through semiconductor vias (TSVs) 134 passing through the semiconductor substrate 132, a plurality of first conductive contacts 136 disposed on the first surface 132a of the semiconductor substrate 132, and a plurality of second conductive contacts 138 disposed on the second surface 132b of the semiconductor substrate 132. In some embodiments in which the semiconductor substrate 132 is a silicon substrate, the through semiconductor vias 134 are referred to as the through silicon vias. Each of the first conductive contacts 136 and each of the second conductive contacts 138 are physically and electrically connected to two opposing ends of one of the TSVs 134. The second surface 132b of the semiconductor substrate 132 faces the second conductive features 126 of the bottom die 120. In some embodiments, the top die 130 is provided with a conductive bonding layer SJ disposed on the second conductive contacts 138. The top die 130 may be aligned with and bonded to the second conductive features 126 of the bottom die 120 through the conductive bonding layer SJ. For example, the conductive bonding layer SJ is a conductive paste such as solder paste, copper paste, silver paste, or the like. It should be appreciated that only one top die 120 including TSVs 134 is illustrated in the drawings, but more than one top dies may be stacked on the bottom die to form the die stack, and the conductive bonding layer(s) may be bonded between two adjacent top dies depending on the product requirements.

Referring to FIG. 1D and FIG. 1E, an insulating encapsulation 140 including through holes TH is formed on the backside RDL 110 and encapsulates the die stack DS. A plurality of through insulating vias (TIVs) 150 is formed in the through holes TH of the insulating encapsulation 140 and electrically connected to the backside RDL 110. The through holes TH of the insulating encapsulation 140 may expose at least a portion of the patterned conductive layer 112 of the backside RDL 110, and the TIVs 150 formed inside the through holes TH may be physically and electrically connected to the portion of the patterned conductive layer 112 of the backside RDL 110.

In some embodiments, the manufacturing method of the insulating encapsulation 140 and the TIVs 150 includes at least the following steps. An insulating material (e.g., epoxy molding compound (EMC), molding underfill (MUF), or other suitable electrically insulating materials; not shown) is formed on the first surface 110a of the backside RDL 110 using a molding process or other suitable techniques. The die stack DS1 may be over-molded. The insulating material may fill the gaps between the top and bottom dies 120 and 130. Next, a portion of the insulating material is removed to form the through holes TH using a laser drilling process, a mechanical drilling process, lithography and etching processes, or other suitable process. In some embodiments in which a laser drilling process is employed, the through holes TH may be tapered toward the backside RDL 110. The inner sidewalls of the insulating material corresponding to the through holes TH may be slanted. The slanted angles of the inner sidewalls may be adjusted based on design requirements. Alternatively, the inner sidewalls of the insulating material may be substantially vertical depending on the employed forming method of the through holes TH. Subsequently, a conductive material (e.g., solder, copper, aluminium, nickel, etc.) is formed inside the through holes TH to form the TIVs 150 using printing, dispensing, plating, sputtering, or other suitable deposition process.

A planarization process (e.g., grinding and/or chemical mechanical polishing (CMP)) is optionally performed. For example, during the planarization process, the insulating material covering the tops of the first conductive contacts 136 of the top die 130 and the tops of the second conductive features 128 of the bottom die 120 may be removed until at least a portion of the first conductive contacts 136 and the second conductive features 128 are exposed for further electrical connection. The TIVs 150, the first conductive contacts 136, and the second conductive features 128 may be slightly grinded during the planarization process. In some embodiments, after performing the planarization process, a top surface 140a of the insulating encapsulation 140 is substantially coplanar with top surfaces 150a of the TIVs 150, top surfaces 128a of the second conductive features 128 of the bottom die 120, and top surfaces 136a of the first conductive contacts 136. In some embodiments in which a laser drilling process is employed to form the through holes TH, the area of the top surface 150a of each TIVs 150 is greater than the area of a bottom surface 150b of the corresponding TIV 150. Alternatively, the surface areas of the top surface 150a and the bottom surface 150b may be substantially equal. In other embodiments, after forming the through holes TH, the insulating material is thinned to expose portions of the top surfaces 136a of the first conductive contacts 136 and the top surfaces 128a of the second conductive features 128, and then the conductive material is filled in the through holes TH to form the TIVs.

Referring to FIG. 1F, a front side RDL 160 is formed on the insulating encapsulation 140 to be physically and electrically connected to the die stack DS1 and the TIVs 150. The front side RDL 160 includes at least one patterned dielectric layer 162 and at least one patterned conductive layer 164. The patterned conductive layer 164 includes conductive lines, conductive vias, conductive pads, etc. The manufacturing method of the front side RDL 160 includes at least the following steps. The patterned dielectric layer 162 is formed on the top surface 140a of the insulating encapsulation 140, the top surfaces 150a of the TIVs 150, the top surfaces 128a of the second conductive features 128, and the top surfaces 136a of the first conductive contacts 136 using deposition, lithography and etching processes, or other suitable techniques. The patterned dielectric layer 162 includes openings exposing at least a portion of the top surfaces 150a of the TIVs 150, at least a portion of the top surfaces 128a of the second conductive features 128, and at least a portion of the top surfaces 136a of the first conductive contacts 136. Subsequently, the patterned conductive layer 164 is formed on the patterned dielectric layer 162 and also formed inside the openings of the patterned dielectric layer 162 using patterning and metallization process described above, such that the patterned conductive layer 164 is physically and electrically connected to the TIVs 150, the second conductive features 128, and the first conductive contacts 136.

The aforementioned steps may be performed multiple times to obtain a multi-layered redistribution structure. Alternatively, the patterned conductive layer 164 may be formed prior to the patterned dielectric layer 162. In some embodiments, the topmost one of the patterned conductive layer 164 may include conductive pads or UBM patterns for a ball mounting process. It should be noted that the front side RDL 160 illustrated in FIG. 1F is only an illustrative example, and the numbers of the patterned conductive layer 164 and the patterned dielectric layer 162 and the forming sequence thereof depend on the circuit design.

Referring to FIG. 1G, a plurality of front side conductive terminals 170 is formed on the front side RDL 160 to be connected to the patterned conductive layer 162. For example, the front side conductive terminals 170 include conductive balls, conductive pillars, conductive bumps or a combination thereof. The front side conductive terminals 170 may be formed by, for example, a ball mounting process, a plating process or other suitable process. Other possible forms and shapes of the front side conductive terminals 170 may be used according to the design requirement. A soldering process and a reflowing process are optionally performed for enhancement of the adhesion between the front side conductive terminals 170 and the front side RDL 160. The front side conductive terminals 170 may be electrically coupled to the die stack DS1 through the front side RDL 160.

After forming the front side conductive terminals 170, the temporary carrier 50 may be removed from the backside RDL 110. In certain embodiments in which the de-conductive bonding layer is formed between the temporary carrier 50 and the backside RDL 110, the external energy such as UV laser, visible light or heat, may be applied to the de-conductive bonding layer so that the second surface 110b of the backside RDL 110 may be separated from the temporary carrier 50. The patterned conductive layer 112 on the second surface 110b may be exposed for further electrical connection.

Referring to FIG. 1H, a plurality of backside conductive terminals 180 is formed on the second surface 110b of the backside RDL 110 to be connected to the patterned conductive layer 112. The forming process and the material of the backside conductive terminals 180 may be similar to those of the front side conductive terminals 170. In some embodiments, the backside conductive terminals 180 are electrically coupled to the die stack DS1 through backside RDL 110, the TIVs 150, and the front side RDL 160. In some embodiments, the front side conductive terminals 170 have finer pitches than the backside conductive terminals 180. The front side conductive terminals 170 and the backside conductive terminals 180 may be of different sizes. It should be noted that the sizes of the front side conductive terminals 170 and the backside conductive terminals 180 shown in FIG. 1H are only illustrative example. In some embodiments, the sizes of the front side conductive terminals 170 and the backside conductive terminals 180 are adjusted depending on the types of the device component(s) to be mounted on. In some embodiments, the aforementioned processes are performed at wafer or panel level, and a singulation process may be performed to separate the structures from one another to form a plurality of semiconductor packages SP1. The manufacturing process of a semiconductor package SP1 is substantially completed as shown in FIG. 1H.

The semiconductor package SP1 may be referred to as a fan-out package. The semiconductor package SP1 includes the die stack DS1, the insulating encapsulation 140 encapsulating the die stack DS1, the front side RDL 160 and the backside RDL 110 disposed on two opposite sides of the insulating encapsulation 140, and the TIVs 150 disposed aside the die stack DS1 and extending through the insulating encapsulation 140 to be electrically connected to the front side RDL 160 and the backside RDL 110. The die stack DS1 includes the bottom die 120 and the top die 130 stacked upon one another and electrically connected to the bottom die 120. The top die 130 includes TSVs 134 disposed therein, and the bottom die 120 includes the first and second conductive features 126 and 128 having different thicknesses. The front side RDL 160 is connected to the TSVs 134 of the top die 130. The first conductive features 126 may be connected to the top die 130, the second conductive features 128 may be disposed aside the first conductive features 126 and connected to the front side RDL 160, where the second conductive features 128 may be thicker than the first conductive features 126. Each of TSVs 134 of the top die 130 has two opposing ends, and one end of each TSV 134 is connected to the first conductive contacts 136 and the other end of the TSV 134 is connected to the second conductive contacts 138. The second conductive contacts 138 may be bonded to the first conductive features 126 of the bottom die 120 through the conductive bonding layer SJ, and the first conductive contacts 136 is connected to the front side RDL 160. The TIVs 150 may be tapered in a direction from the front side RDL 160 toward the backside RDL 110.

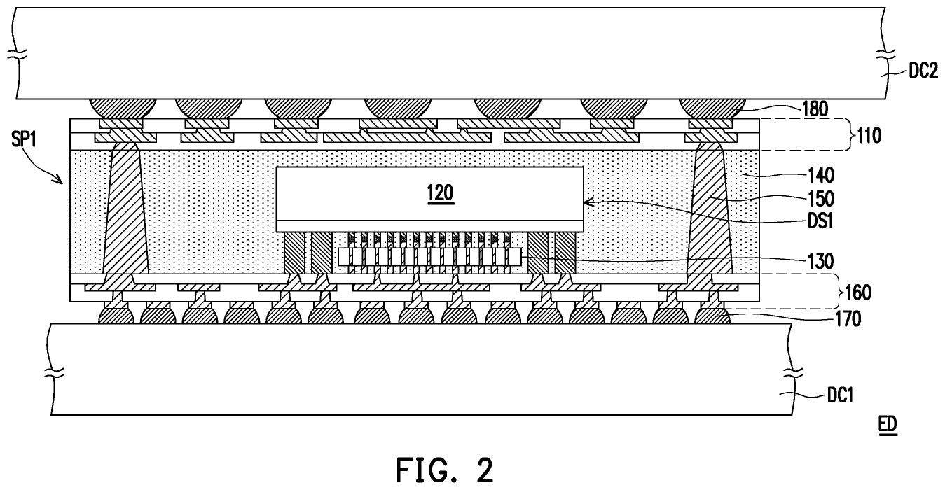

FIG. 2 is a schematic cross-sectional view illustrating an application of a semiconductor package according to an embodiment of the disclosure. Referring to FIG. 2, a first device component DC1 and a second device component DC2 are optionally connected to the two opposing sides of the semiconductor package SP1 to form an electronic device ED. For example, the first device component DC1 and the second device component DC2 may be or may include a semiconductor package having the same or different functions to the semiconductor package SP1, a package substrate, a printed circuit board, a system board, a mother board, etc. In some embodiments, the first device component DC1 is stacked on the semiconductor package SP1, and the front side conductive terminals 170 may be reflowed to be bonded therebetween. Similarly, the second device component DC2 may be disposed on the semiconductor package SP1 opposite to the first device component DC1, and then the backside conductive terminals 180 may be reflowed to be bonded between the semiconductor package SP1 and the second device component DC2. An underfill layer is optionally formed between the semiconductor package SP1 and the first device component DC1 and/or between the semiconductor package SP1 and the second device component DC2 to laterally wrap the front side conductive terminals 170 and/or the backside conductive terminals 180, thereby improving the reliability of the electronic device ED.

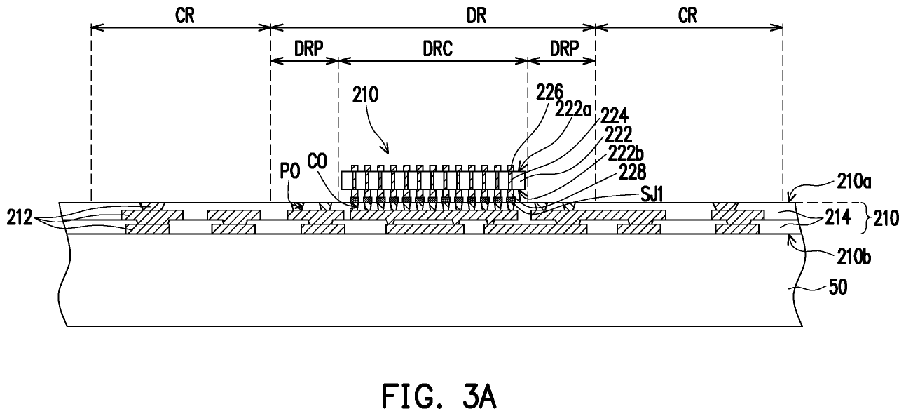

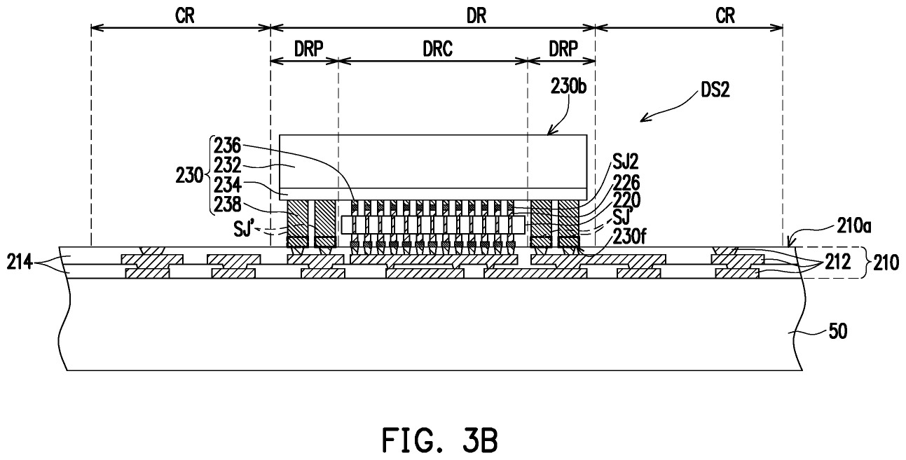

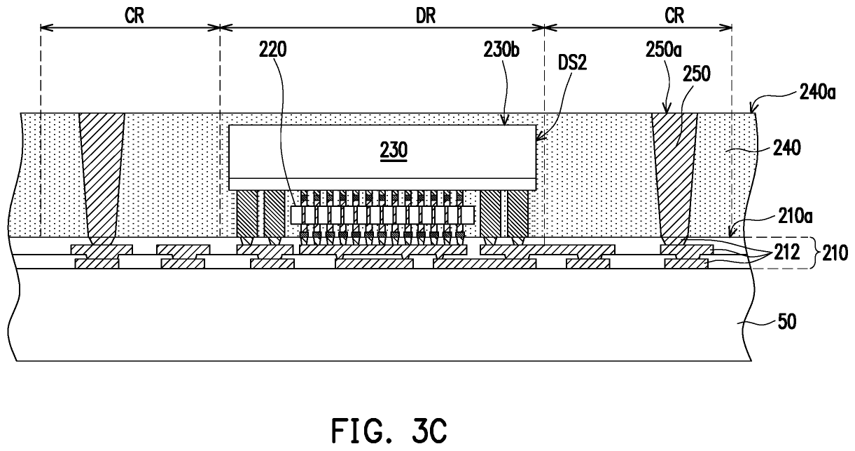

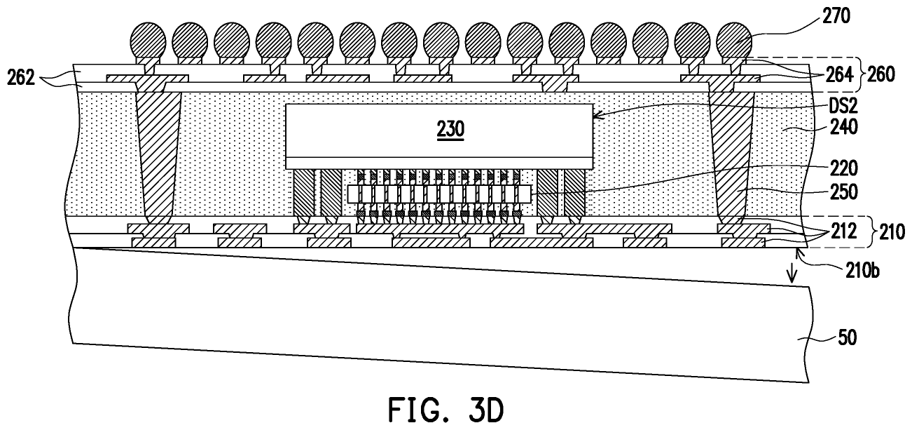

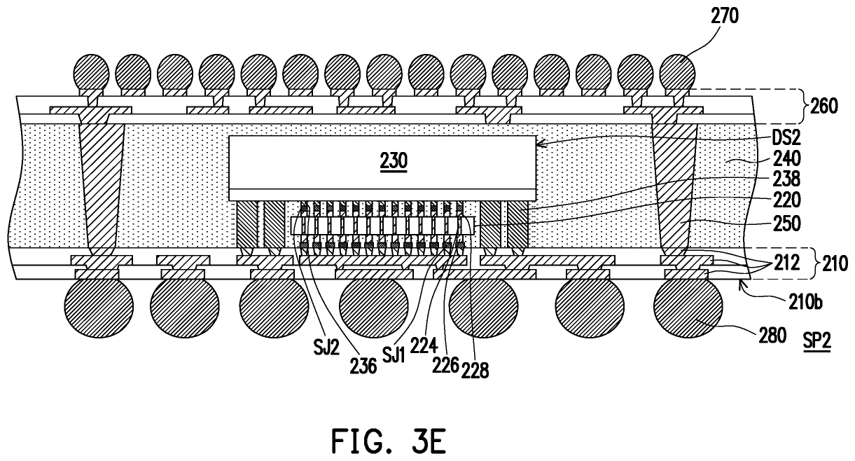

FIG. 3A and FIG. 3E are schematic cross-sectional views illustrating a manufacturing method of a semiconductor package according to an embodiment of the disclosure. Referring to FIG. 3A and FIG. 3B, a front side RDL 210 is formed on the temporary carrier 50, and a die stack DS2 including a bottom die 220 and a top die 230 is disposed on the front side RDL 210. The front side RDL 210 has a first surface 210a and a second surface 210b opposite to the first surface 210a. The second surface 210b may be planar and may be directly or indirectly bonded to the temporary carrier 50. The front side RDL 210 includes at least one patterned conductive layer 212 and at least one patterned dielectric layer 214. The manufacturing method and the material of the front side RDL 210 may be similar to those of the backside RDL 110 described in FIG. 1A. A portion of the patterned conductive layer 212 is formed on the first surface 210a and the second surface 210b and may be revealed by the patterned dielectric layer 214 for further electrical connection. The other portion of the patterned conductive layer 212 may be embedded in the patterned dielectric layer 214. The patterned conductive layer 212 includes conductive lines, conductive vias, conductive pads, etc. In some embodiments, the portion of the patterned conductive layer 212 located at the second surface 210b includes conductive pads or UBM patterns for ball mounting.

The first surface 210a of the front side RDL 210 includes the die attach region DR and the connecting region CR surrounding the die attach region DR. The portion of the patterned conductive layer 212 located at the first surface 210a may be revealed and formed in the connecting region CR and the die attach region DR for connecting the subsequently bonded top die and the subsequently formed TIVs. In some embodiments, the die attach region DR includes a central part DRC and a peripheral part DRP enclosing the central part DRC. The topmost one of the patterned dielectric layer 214 may include a plurality of central openings CO formed corresponding to the central part DRC and a plurality of peripheral openings PO formed corresponding to the peripheral part DRP. The central openings CO and the peripheral openings PO may be filled by the conductive vias of the topmost one of the patterned conductive layer 212. The conductive vias of the topmost one of the patterned conductive layer 212 corresponding to the central openings CO may be subsequently bonded to the bottom die 220. The conductive vias of the topmost one of the patterned conductive layer 212 corresponding to the peripheral openings PO may be subsequently bonded to the top die (shown in FIG. 3B). In some embodiments, the conductive vias of the topmost one of the patterned conductive layer 212 corresponding to the central openings CO may have finer pitches than those conductive vias corresponding to the peripheral openings PO. Alternatively, the central openings CO and/or the peripheral openings PO exposing the underlying patterned conductive layer 212 may be empty and may be subsequently filled by the conductive bonding layer to form solder joints between the die stack DS2 and the front side RDL 210.

Continue to FIG. 3A, the bottom die 220 includes a semiconductor substrate 222 having first and second surfaces 222a and 222b opposite to each other, a plurality of TSVs 224 penetrating through the semiconductor substrate 222, a plurality of first conductive contacts 226 disposed on a first surface 222a of the semiconductor substrate 222, and a plurality of second conductive contacts 228 disposed on a second surface 222b of the semiconductor substrate 222. The bottom die 220 may be similar to the top die 130 described in FIG. 1C. In some embodiments, the bottom die 220 is disposed on the first surface 210a of the front side RDL 210 corresponding to the central part DRC through a flip chip process. The first conductive bonding layer SJ1 may be interposed between the bottom die 220 and the patterned conductive layer 212 on the first surface 210a for improving the adhesion therebetween. The material of the first conductive bonding layer SJ1 may be similar to the conductive bonding layer SJ described in FIG. 1C. Alternatively, the first conductive bonding layer SJ1 is omitted or an underfill layer may be formed on the front side RDL 210 to fill the gaps between the bottom die 220 and the front side RDL 210.

Referring to FIG. 3B, a top die 230 is disposed on the bottom die 220 to form a die stack DS2 on the front side RDL 210. The top die 230 has a front side 230f and a back side 230b opposite to each other. In some embodiments, the top die 230 is bonded to the bottom die 220 and the front side RDL 210 through a flip chip process, such that the front side 230f faces the bottom die 220 and the front side RDL 210. The top die 230 may include a semiconductor substrate 232, an interconnecting layer 234 disposed on the semiconductor substrate 232, and a plurality of first and second conductive features 236 and 238 disposed on the interconnecting layer 234 and distributed at the front side 230f. The top die 230 may be similar to the bottom die 120 described in FIG. 1B.

After stacking the top die 230 on the bottom die 220, the first conductive features 236 of the top die 230 are located corresponding to the central part DRC and bonded to the bottom die 220. In some embodiments, the second conductive bonding layer SJ2 is interposed between the first conductive features 236 of the top die 230 and the first conductive contacts 226 of the bottom die 220 to enhance the adhesion and the alignment therebetween. The second conductive bonding layer SJ2 may be similar to the first conductive bonding layer SJ1. The top die 230 may be larger than the bottom die 220 so that the entirety of the top die 130 may be covered by the bottom die 120. After stacking the top die 230 on the bottom die 220, the bottom die 220 is encircled by the second conductive features 238 of the top die 230. The second conductive features 238 of the top die 230 may be located corresponding to the peripheral part DRP and bonded to the patterned conductive layer 212 on the first surface 210a of the front side RDL 210. In some embodiments, an additional conductive bonding layer SJ′ is interposed between the patterned conductive layer 212 of the front side RDL 210 and the second conductive features 238 of the top die 230. Alternatively, the additional conductive bonding layer SJ′ is omitted, and the second conductive features 238 are directly bonded to the patterned conductive layer 212. Accordingly, the additional conductive bonding layer SJ′ in FIG. 3B is illustrated as dashed to indicate it may or may not be present.

Referring to FIG. 3C, an insulating encapsulation 240 is formed on the first surface 210a of the front side RDL 210 to encapsulate the die stack DS2. The TIVs 250 are disposed on the first surface 210a of the front side RDL 210 corresponding to the connecting region CR and laterally embedded in the insulating encapsulation 240. In some embodiments, the TIVs 250 are tapered toward the front side RDL 210. The materials and the forming processes of the insulating encapsulation 240 and the TIVs 250 may be similar to those of the insulating encapsulation 140 and the TIVs 150 described in FIG. 1D and FIG. 1E, so the details thereof are simplified for brevity. For example, the die stack DS2 is over-molded with the insulating material, and then a portion of the insulating material is removed to form the insulating encapsulation 240 with the though holes. The through holes may expose the underlying patterned conductive layer 212 of the front side RDL 210. Subsequently, the conductive material is filled inside the through holes of the insulating encapsulation 240 to form the TIVs 250 connecting the underlying patterned conductive layer 212 of the front side RDL 210. A planarization process is optionally performed. In some embodiments, the top surface 240a of the insulating encapsulation 240 is substantially coplanar with the top surfaces 250a of the TIVs 250.

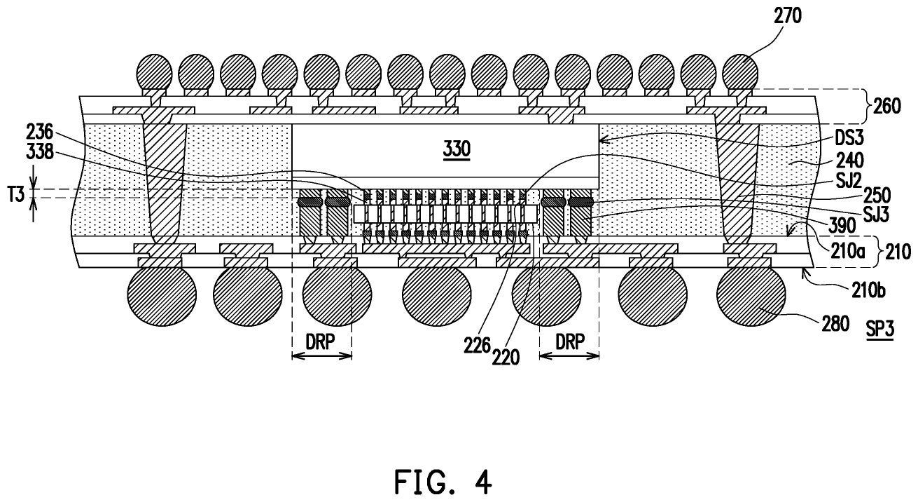

After the forming processes of the insulating encapsulation 240, the back side 230b of the top die 230 may be covered by the insulating encapsulation 240. The thickness of the TIVs 250 may be greater than the thickness of the die stack DS2. Alternatively, a thinning process (e.g., grinding) may be performed to reduce the thickness of the insulating material until the back side 230b of the top die 230 is exposed by the insulating material, thereby reducing the overall thickness of the semiconductor package (e.g., the structure shown in FIG. 4).

Referring to FIG. 3D, a backside RDL 260 is formed on the insulating encapsulation 240 and the TIVs 250, and a plurality of backside conductive terminals 270 is formed on the backside RDL 260. The backside RDL 260 includes at least one patterned dielectric layer 262 and at least one patterned conductive layer 264. The forming process of the backside RDL 260 and the backside conductive terminals 270 may be similar to those of the front side RDL 160 and the front side conductive terminals 170 described in FIG. 1F and FIG. 1G, so the details thereof are simplified for brevity. For example, the patterned dielectric layer 262 is formed on the top surface 240a of the insulating encapsulation 240 and the top surfaces 250a of the TIVs 250. The patterned dielectric layer 262 includes openings exposing at least a portion of the top surfaces 250a of the TIVs 250. Subsequently, the patterned conductive layer 264 is formed on the surface of the patterned dielectric layer 262 and also formed inside the openings of the patterned dielectric layer 262 to be connected to the TIVs 250. The patterned conductive layer 264 of the backside RDL 260 may be electrically coupled to the die stack DS2 through the TIVs 250 and the front side RDL 210. After forming the backside RDL 260, the backside conductive terminals 270 are formed on the backside RDL 260 so that the die stack DS2 is electrically coupled to the backside conductive terminals 270 through the front side RDL 210, the TIVs 250, and the backside RDL 260.

Subsequently, the temporary carrier 50 is removed to expose the second surface 210b of the front side RDL 210. The removing process of the temporary carrier 50 may be similar to that of the temporary carrier 50 described in FIG. 1G, so the details thereof are omitted for brevity. After removing the temporary carrier 50, the patterned conductive layer 212 located at the second surface 210b may be exposed for further electrical connection.

Referring to FIG. 3E, a plurality of front side conductive terminals 280 is formed on the second surface 210b of the front side RDL 210 to be connected to the patterned conductive layer 212. The forming process and the material of the front side conductive terminals 280 may be similar to those of the backside conductive terminals 180 described in FIG. 1H. The front side conductive terminals 280 may be electrically coupled to the die stack DS2 through the front side RDL 210. In some embodiments, the backside conductive terminals 270 have smaller sizes and/or finer pitches than the front side conductive terminals 280. It should be noted that the sizes and pitches of the front side conductive terminals 170 and the backside conductive terminals 180 may depend on the product requirements. A singulation process may be performed and the manufacturing process of a semiconductor package SP2 is substantially completed as shown in FIG. 3E.

The semiconductor package SP2 includes the die stack DS2, the insulating encapsulation 240 encapsulating the die stack DS2, the front side RDL 210 and the backside RDL 260 disposed on two opposite sides of the insulating encapsulation 240, and the TIVs 250 disposed aside the die stack DS2 and extending through the insulating encapsulation 240 to be electrically connected to the front side RDL 210 and the backside RDL 260. The die stack DS2 includes the bottom die 220 and the top die 230 stacked upon one another and electrically connected to the bottom die 220. The bottom die 220 includes TSVs 224 disposed therein, and the top die 230 includes the first and second conductive features 236 and 238 having different thicknesses. The front side RDL 210 is connected to the TSVs 224 of the bottom die 220. The first conductive features 236 may be connected to the bottom die 220, the second conductive features 238 may be disposed aside the first conductive features 236 and connected to the front side RDL 210, where the second conductive features 238 may be thicker than the first conductive features 236. Each of TSVs 224 of the bottom die 220 has two opposing ends, and one end of each TSV 224 is connected to the first conductive contacts 226 and the opposing end of the TSV 224 is connected to the second conductive contacts 228. The second conductive contacts 228 may be bonded to the first conductive features 236 of the top die 230 through the second conductive bonding layer SJ2, and the first conductive contacts 226 is connected to the front side RDL 210 through the first conductive bonding layer SJ1. The TIVs 250 may be tapered in a direction from the backside RDL 260 toward the front side RDL 210. The thickness of the TIVs 250 may be greater than the thickness of the die stack DS2.

FIG. 4 is a schematic cross-sectional view illustrating a semiconductor package according to an embodiment of the disclosure. Referring to FIG. 4 and FIG. 3D, a semiconductor package SP3 is provided. The semiconductor package SP3 may be similar to the semiconductor package SP2. The differences between the semiconductor packages SP2 and SP3 include the top die 330 of the die stack DS3, a third conductive bonding layer SJ3, and a plurality of conductive connectors 390. For example, the second conductive features 338 of the top die 330 of the semiconductor package SP3 have thicknesses less than the thicknesses of the second conductive features 238 of the die stack DS2 of the semiconductor package SP2. In some embodiments, a thickness T3 of one of the second conductive features 338 is substantially equal to that of one of the first conductive features 236. Alternatively, the thickness T3 of one the second conductive features 338 may be greater or less than that of one of the first conductive features 236.

The conductive connectors 390 may be formed on the front side RDL 210 corresponding to the peripheral part DRP to be physically and electrically connected to the underlying patterned conductive layer 212. In some embodiments, the conductive connectors 390 are formed on the first surface 210a of the front side RDL 210 prior to a disposing process of the bottom die 220. The conductive connectors 390 and the underlying conductive vias of the patterned conductive layer 212 may be formed during the same process. Alternatively, the conductive connectors 390 are formed after disposing the bottom die 220. After forming the conductive connectors 390 and disposing the bottom die 220, the top die 330 is stacked on the bottom die 220 and the conductive connectors 390. For example, the second conductive bonding layer SJ2 is interposed between the first conductive features 236 of the top die 330 and the first conductive contacts 226 of the bottom die 220, and the third conductive bonding layer SJ3 is interposed between the second conductive features 338 of the top die 330 and the conductive connectors 390. The thickness of the conductive connectors 390 may be adjusted depending on the thickness T3 of the second conductive features 338 of the top die 330 and the thickness of the third conductive bonding layer SJ3.

FIG. 5A to FIG. 5D are schematic cross-sectional views illustrating a manufacturing method of a semiconductor package according to an embodiment of the disclosure. Referring to FIG. 5A, a backside RDL 410 is formed on the temporary carrier 50, and a bottom die 420 is disposed on the backside RDL 410. The backside RDL 410 has a first surface 410a and a second surface 410b opposite to each other, and the second surface 410b may be planar and may be directly or indirectly connected to the temporary carrier 50. The backside RDL 410 includes at least one patterned conductive layer 412 and at least one patterned dielectric layer 414. The manufacturing method and the material of the backside RDL 410 may be similar to those of the front side RDL 210 described in FIG. 3A. A portion of the patterned conductive layer 412 may be located at the first surface 410a and the second surface 410b and may be revealed by the patterned dielectric layer 414 for further electrical connection. The other portion of the patterned conductive layer 412 may be embedded in the patterned dielectric layer 414. The patterned conductive layer 412 includes conductive lines, conductive vias, conductive pads, etc. In some embodiments, the portion of the patterned conductive layer 412 located at the second surface 410b includes conductive pads or UBM patterns for ball mounting.

After forming the backside RDL 410, the bottom die 420 is disposed on the first surface 410a of the backside RDL 410. The bottom die 420 includes a semiconductor substrate 421 having a front surface 421a and a back surface 421b opposite to each other, an interconnecting layer 422 disposed on the front surface 421a of the semiconductor substrate 421, a plurality of TSVs 423 passing through the semiconductor substrate 421 and electrically connected to the interconnecting layer 422, a plurality of conductive contacts 424 disposed on the back surface 421b of the semiconductor substrate 421 and electrically connected to the TSVs 423, and a plurality of first and second conductive features 425 and 426 disposed on and electrically connected to the interconnecting layer 422. The first conductive features 425 may be surrounded by the second conductive features 426. In some embodiments, the first conductive features 425 are thinner than the second conductive features 426. The conductive contacts 424 may be aligned with and directly bonded to the patterned conductive layer 412 on the first surface 410a of the backside RDL 410. In some embodiments, the underfill layer UF is interposed between the conductive contacts 424 of the bottom die 420 and the first surface 410a of the backside RDL 410 to enhance the adhesion therebetween. Alternatively, the underfill layer UF is omitted, and the conductive contacts 424 of the bottom die 420 are bonded to the patterned conductive layer 412 through, for example, solder joints. Accordingly, the underfill layer UF in FIG. 5A is illustrated as dashed to indicate it may or may not be present.

Referring to FIG. 5B, a top die 430 is disposed on the bottom die 420 to form a die stack DS4 on the backside RDL 410. The top die 430 has a front side 430f and a back side 430b opposite to each other. In some embodiments, the top die 430 is bonded to the bottom die 420 through a flip chip process, such that the front side 430f faces the bottom die 420. The top die 430 may include a semiconductor substrate 432, a plurality of conductive bumps 434 disposed on the semiconductor substrate 432. For example, the conductive bumps 434 are aligned with and bonded to the first conductive features 425 through the conductive bonding layer SJ. After bonding, the top die 430 is surrounded by the second conductive features 426 of the bottom die 420.

Referring to FIG. 5C, an insulating encapsulation 440 is formed on the first surface 410a of the backside RDL 410 to encapsulate the die stack DS4. The TIVs 450 are disposed on the first surface 410a of the backside RDL 410 and may be laterally embedded in the insulating encapsulation 440. In some embodiments, the TIVs 450 are tapered toward the backside RDL 410. The materials and the forming processes of the insulating encapsulation 440 and the TIVs 450 may be similar to those of the insulating encapsulation 140 and the TIVs 150 described in FIG. 1D and FIG. 1E, so the details thereof are simplified for brevity. For example, the die stack DS4 is over-molded with the insulating material. Next, a thinning process is performed on the insulating material until at least a portion of the second conductive features 426 is exposed. In some embodiments, when the thinning process is performed, the back side 430b of the top die 430 may be slightly grinded, so that the overall thickness of the die stack DS4 is reduced.

Subsequently, a portion of the thinned insulating material is removed to form the insulating encapsulation 440 with the though holes. The through holes may expose the underlying patterned conductive layer 412 of the backside RDL 410. Afterwards, the conductive material may be filled in the through holes of the insulating encapsulation 440 to form the TIVs 450 connecting the underlying patterned conductive layer 412 of the backside RDL 410. A planarization process is optionally performed. In some embodiments, the top surface 440a of the insulating encapsulation 440 is substantially coplanar with the top surfaces 450a of the TIVs 450, the top surfaces 426a of the second conductive features 426, and the back side 430b of the top die 430. In other embodiments, the through holes may be formed before reducing the thickness of the insulating material. It should be appreciated that the aforementioned steps are an illustrative example, and the manufacturing processes of the insulating encapsulation 440 and the TIVs 450 may be adjusted depending on the process requirements, and the shapes of the through holes of the insulating encapsulation 440 and the shapes of the TIVs 450 may also be adjusted.

Continue to FIG. 5C, after forming the insulating encapsulation 440 and the TIVs 450, a front side RDL 460 is formed on the insulating encapsulation 440, the die stack DS4, and the TIVs 450. A plurality of front side conductive terminals 470 is formed on the front side RDL 460. The front side RDL 460 includes at least one patterned dielectric layer 462 and at least one patterned conductive layer 464. The forming processes of the front side RDL 460 and the front side conductive terminals 470 may be similar to those of the front side RDL 160 and the front side conductive terminals 170 described in FIG. 1F and FIG. 1G, so the details thereof are simplified for brevity. For example, the patterned dielectric layer 462 is formed on the top surface 440a of the insulating encapsulation 440, the top surfaces 450a of the TIVs 450, the top surfaces 426a of the second conductive features 426, and the back side 430b of the top die 430. The patterned dielectric layer 462 includes openings exposing at least a portion of the top surfaces 450a of the TIVs 450 and at least a portion of the top surfaces 426a of the second conductive features 426. Subsequently, the patterned conductive layer 464 is formed on the surface of the patterned dielectric layer 462 and also formed inside the openings of the patterned dielectric layer 462 to be connected to the TIVs 450. The patterned conductive layer 464 of the front side RDL 460 may be electrically connected to the second conductive features 426 of the die stack DS4. After forming the front side RDL 460, the front side conductive terminals 470 are formed on the front side RDL 460, so that the die stack DS4 is electrically coupled to the front side conductive terminals 470 through the front side RDL 460.

Subsequently, the temporary carrier 50 is removed to expose the second surface 410b of the backside RDL 410. The removing process of the temporary carrier 50 may be similar to that of the temporary carrier 50 described in FIG. 1G, so the details thereof are omitted for brevity. After removing the temporary carrier 50, the patterned conductive layer 412 on the second surface 410b may be exposed for further electrical connection.

Referring to FIG. 5D, a plurality of backside conductive terminals 480 is formed on the second surface 410b of the backside RDL 410 to be connected to the patterned conductive layer 412. The forming process and the material of the backside conductive terminals 480 may be similar to those of the backside conductive terminals 180 described in FIG. 1H. The backside conductive terminals 480 may be electrically coupled to the die stack DS4 through backside RDL 410. In some embodiments, the backside conductive terminals 480 have smaller sizes and/or finer pitches than the front side conductive terminals 470. It should be noted that the sizes and pitches of the front side conductive terminals 470 and the backside conductive terminals 480 may depend on the product requirements. A singulation process may be performed and the manufacturing process of a semiconductor package SP4 is substantially completed as shown in FIG. 5D.

The semiconductor package SP4 includes the die stack DS4, the insulating encapsulation 440 encapsulating the die stack DS4, the front side RDL 460 and the backside RDL 410 disposed on two opposite sides of the insulating encapsulation 440, and the TIVs 450 disposed aside the die stack DS4 and extending through the insulating encapsulation 440 to be electrically connected to the front side RDL 460 and the backside RDL 410. The die stack DS4 includes a bottom die 420 and a top die 430 stacked upon one another and electrically connected to the bottom die 420. The bottom die 420 includes the TSVs 423 disposed in the semiconductor substrate 421, and the first and second conductive features 425 and 426 having different thicknesses. The backside RDL 410 is connected to the TSVs 423 of the bottom die 420. The first conductive features 425 may be connected to the top die 430, the second conductive features 426 may be disposed aside the first conductive features 425 and connected to the front side RDL 460, where the second conductive features 426 may be thicker than the first conductive feature 425. Each of TSVs 423 of the bottom die 420 has two opposing ends, and one end of each TSV 423 is connected to the backside RDL 410 through the conductive contacts 424, and the other end of the TSV 423 is connected to the interconnecting layer 422 and faces toward the first and second conductive feature 425 and 426. The TIVs 450 may be tapered in a direction from the front side RDL 460 toward the backside RDL 410. The underfill layer UF (illustrated in FIG. 5A) may be disposed between the bottom die 420 and the backside RDL 410.

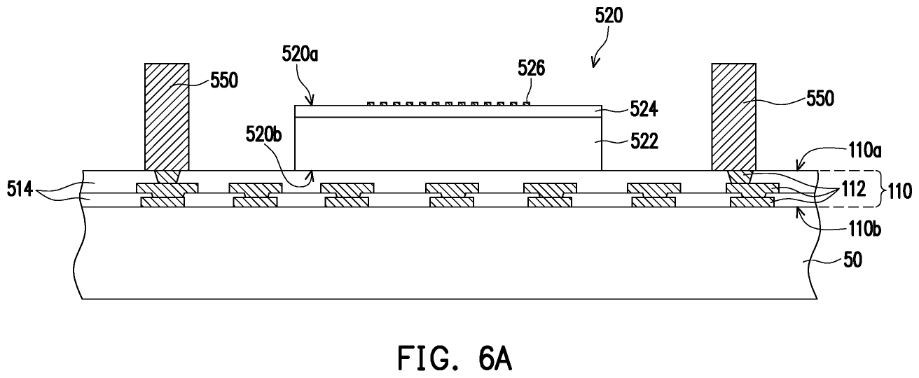

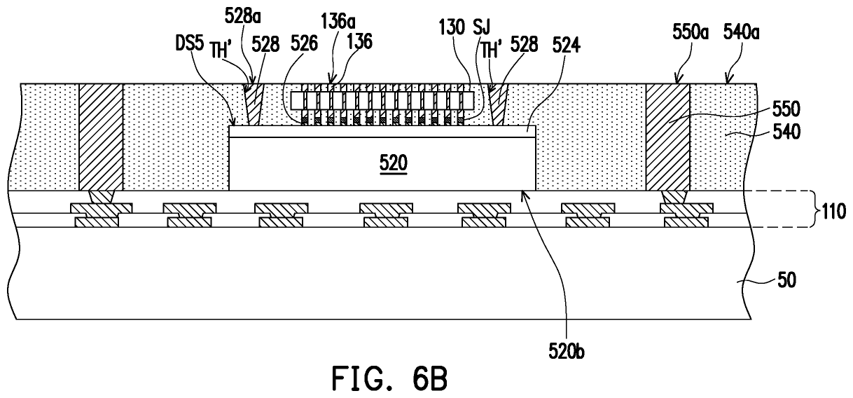

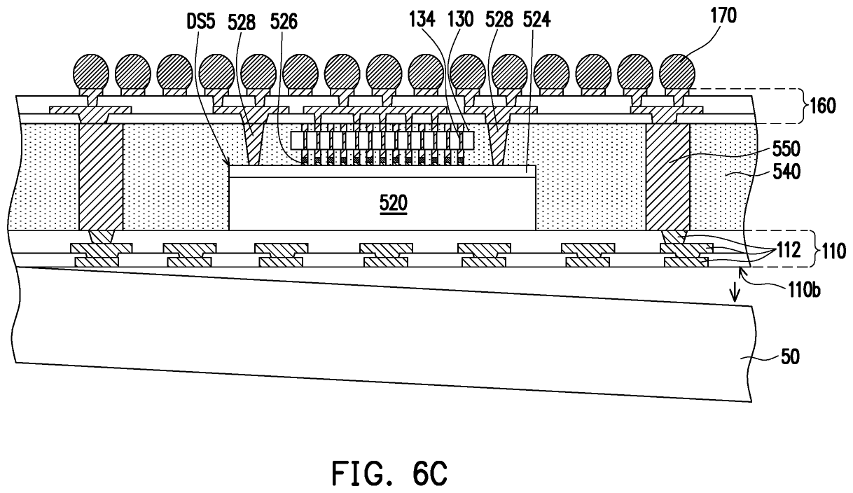

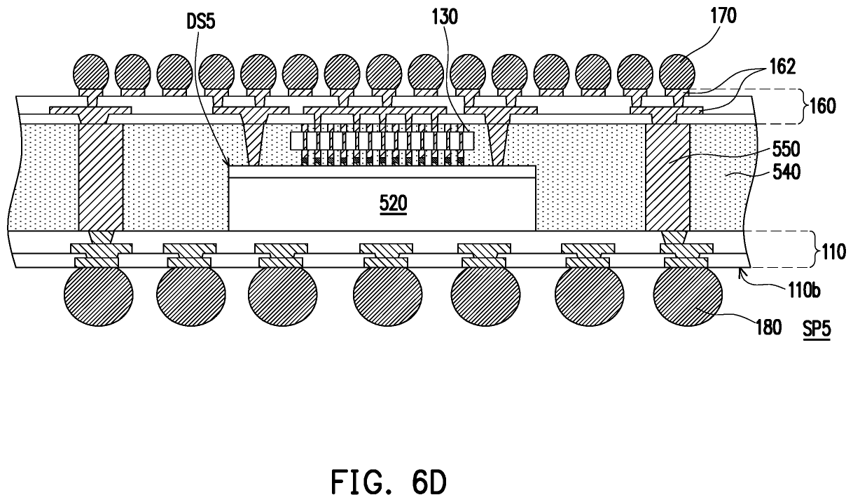

FIG. 6A and FIG. 6D are schematic cross-sectional views illustrating a manufacturing method of a semiconductor package according to an embodiment of the disclosure. Referring to FIG. 6A, the backside RDL 110 including the patterned conductive layer 112 and the patterned dielectric layer 114 is formed on the temporary carrier 50. The manufacturing method and the material of the backside RDL 110 may be similar to those of the backside RDL 110 described in FIG. 1A, so the details thereof are omitted for brevity. After forming the backside RDL 110, a plurality of TIVs 550 and a bottom die 520 are provided on the first surface 110a of the backside RDL 110. In some embodiments, the TIVs 550 are formed on the backside RDL 110 using plating or other suitable deposition process. In some other embodiments, the TIVs 550 and the underlying conductive vias of the patterned conductive layer 112 are deposited during the same process. Alternatively, the TIVs 550 are pre-formed and may be disposed on the backside RDL 110 through a pick and place process. The TIVs 550 may have vertical sidewalls which are substantially perpendicular to the first surface 110a of the backside RDL 110. It should be appreciated that the TIVs 550 may be provided in any suitable forms or shapes (e.g., pillars, balls, etc.) depending on the design requirements. In some embodiments, after providing the TIVs 550, the bottom die 520 is disposed on the backside RDL 110 to be surrounded by the TIVs 550. Alternatively, the bottom die 520 is disposed prior to providing the TIVs 550.

The bottom die 520 may include a semiconductor substrate 522, an interconnecting layer 524 disposed on and electrically connected to the semiconductor substrate 522, and a plurality of first conductive features 526 disposed on and electrically connected to the interconnecting layer 524. The bottom die 520 includes a front side 520a and a back side 520b opposite to each other. The first conductive features 526 may be distributed at the front side 520a, and the back side 520b of the bottom die 520 faces the first surface 110a of the backside RDL 110. In some embodiments, the back side 520b of the bottom die 520 is bonded to the first surface 110a of the backside RDL 110 through the die attach layer. After providing the bottom die 520 and the TIVs 550, the thickness of each of the TIVs 550 is greater than the thickness of the bottom die 520. In some embodiments, the difference between bottom die 520 and the bottom die 120 shown in FIG. 1B lies in that the second conductive features are not initially provided on the interconnecting layer.

Referring to FIG. 6B, the top die 130 is stacked on the bottom die 520. An insulating encapsulation 540 with a plurality of through holes TH′ is formed on the first surface 110a of the backside RDL 110 to encapsulate the top and bottom dies 130 and 520 and the TIVs 550. A plurality of second conductive features 528 is formed in the through holes TH′ of the insulating encapsulation 540 to be electrically connected to the interconnecting layer 524. The top die 130 may be similar to the top die shown in FIG. 1C, and the details thereof are omitted for brevity. In some embodiments, the top die 130 is bonded to the first conductive features 526 of the bottom die 520 through the conductive bonding layer SJ. The top die 130 may be disposed on the central region of the front side 520a of the bottom die 520.

In some embodiments, after stacking the top die 130, the insulating encapsulation 540 with the through holes TH′ is formed on the backside RDL 110. The through holes TH′ may be formed corresponding to the peripheral region of the front side 520a of the bottom die 520 using a laser drilling process, a mechanical drilling process, lithography and etching processes, or other suitable process. In some embodiments in which a laser drilling process is employed, the through holes TH′ may be tapered toward the bottom die 520. In some embodiments, the through holes TH′ expose at least a portion of the circuitry (not shown) of the interconnecting layer 524 for further electrical connection. Next, a conductive material may be formed in the through holes TH′ of the insulating encapsulation 540 to form the second conductive features 528 on the interconnecting layer 524. The second conductive features 528 may be tapered toward the back side 520 of the bottom die 520. In other embodiments, the conductive features 528 have the vertical sidewalls depending on the forming process thereof. A planarization process is optionally performed. In some embodiments, the top surface 540a of the insulating encapsulation 540 is substantially coplanar with the top surfaces 550a of the TIVs 550, the top surfaces 528a of the second conductive features 528, and the top surfaces 136a of the first conductive contacts 136. In alternative embodiments, both of the TIVs and the second conductive features are tapered toward the same direction.

Referring to FIG. 6C, the front side RDL 160 is formed on the insulating encapsulation 540 to be physically and electrically connected to the die stack DS5 and the TIVs 550. Subsequently, the front side conductive terminals 170 are formed on the front side RDL 160 to be connected to the patterned conductive layer 162 so that the front side conductive terminals 170 may be electrically coupled to the die stack DS5 through the front side RDL 160. After forming the front side conductive terminals 170, the temporary carrier 50 may be removed from the backside RDL 110 so that the patterned conductive layer 112 on the second surface 110b may be exposed for further electrical connection. The aforementioned steps may be similar to the manufacturing processes described in FIG. 1F and FIG. 1G, so the detailed descriptions are omitted for brevity.

Referring to FIG. 6D, the backside conductive terminals 180 are formed on the second surface 110b of the backside RDL 110 to be connected to the patterned conductive layer 112. The backside conductive terminals 180 may be electrically coupled to the die stack DS5 through the backside RDL 110, the TIVs 550, and the front side RDL 160. In some embodiments, a singulation process is performed to separate the structures from one another to form a plurality of semiconductor packages SPS. The manufacturing process of a semiconductor package SP5 is substantially completed as shown in FIG. 6D.

The semiconductor package SP5 includes the die stack DS5, the insulating encapsulation 540 encapsulating the die stack DS5, the front side RDL 160 and the backside RDL 110 disposed on two opposite sides of the insulating encapsulation 540, and the TIVs 550 disposed aside the die stack DS5 and extending through the insulating encapsulation 540 to be electrically connected to the front side RDL 160 and the backside RDL 110. The die stack DS5 includes the bottom die 520 and the top die 130 stacked upon one another and electrically connected to the bottom die 520. The top die 130 includes TSVs 134 disposed therein, and the bottom die 520 includes the first and second conductive features 526 and 528 having different thicknesses. The front side RDL 160 is connected to the TSVs 134 of the top die 130. The first conductive features 526 may be connected to the top die 130, the second conductive features 528 may be disposed aside the first conductive features 526 and connected to the front side RDL 160, where the second conductive features 528 may be thicker than the first conductive features 526. Each of TSVs 134 of the top die 130 has two opposing ends respectively connected to the first conductive features 526 of the bottom die 520 and the front side RDL 160. The second conductive features 528 of the bottom die 520 may be tapered in a direction from the front side RDL 160 toward the backside RDL 110.

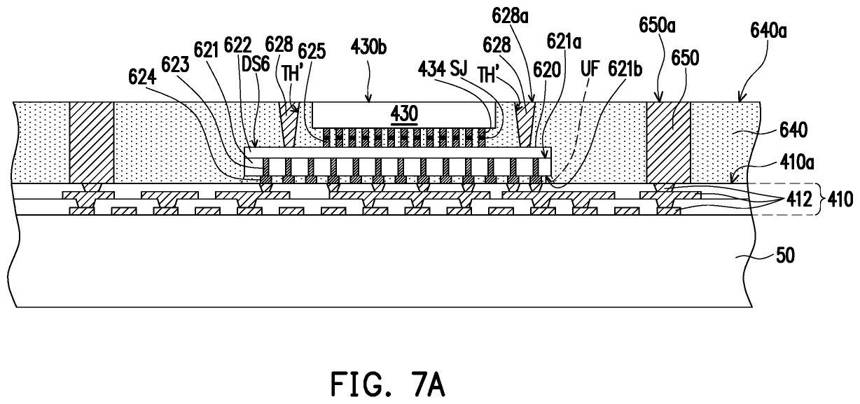

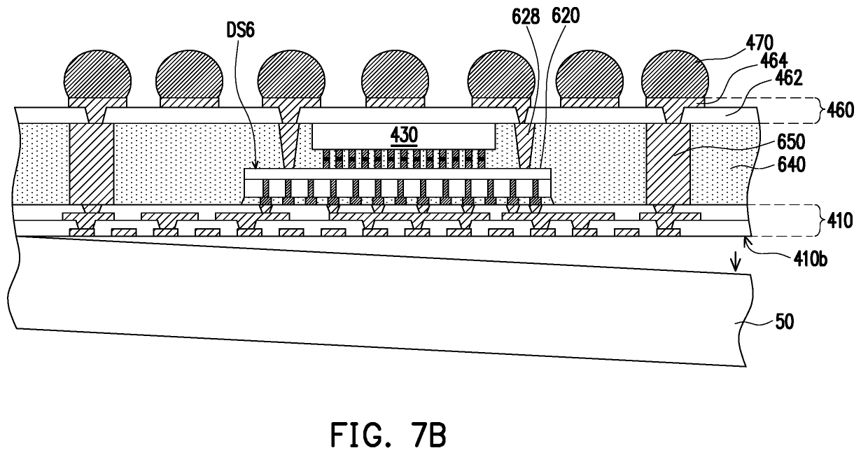

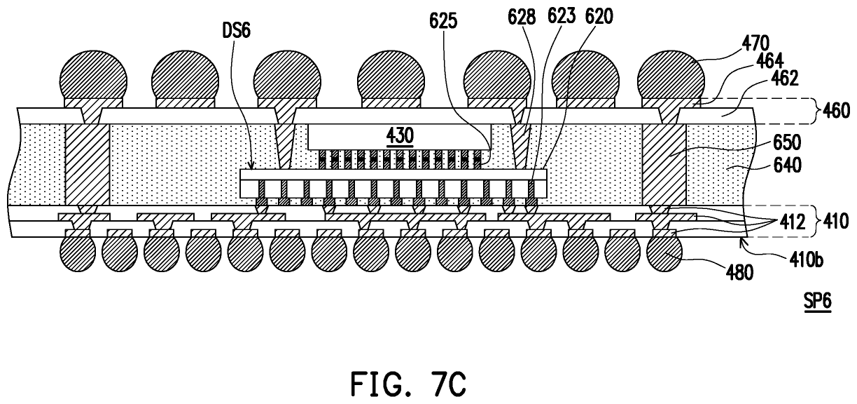

FIG. 7A and FIG. 7C are schematic cross-sectional views illustrating a manufacturing method of a semiconductor package according to an embodiment of the disclosure. Referring to FIG. 7A, the backside RDL 410 is formed on the temporary carrier 50, and a die stack DS6 and the TIVs 650 are disposed on the backside RDL 410. The die stack DS6 may include a bottom die 650 and the top die 430 stacked thereon. In some embodiments, the TIVs 650 are formed prior to a disposing process of the bottom die 650. The TIVs 650 having the vertical sidewalls may be similar to the TIVs 550 shown in FIG. 6A. In some embodiments, the bottom die 650 includes a semiconductor substrate 621 having a front surface 621a and a back surface 621b opposite to each other, an interconnecting layer 622 disposed on the front surface 621a of the semiconductor substrate 621, a plurality of TSVs 623 passing through the semiconductor substrate 621 and electrically connected to the interconnecting layer 622, a plurality of conductive contacts 624 disposed on the back surface 621b of the semiconductor substrate 621 and electrically connected to the TSVs 623, and a plurality of first conductive features 625 disposed on and electrically connected to the interconnecting layer 622. In some embodiments, the underfill layer UF is interposed between the conductive contacts 624 of the bottom die 620 and the first surface 410a of the backside RDL 410 to enhance the adhesion therebetween. Alternatively, the underfill layer UF is omitted, so the underfill layer UF in FIG. 7A is illustrated as dashed to indicate it may or may not be present. The bottom die 650 may be similar to the bottom die 420 shown in FIG. 5A, except that the second conductive features are not provided in the first place. The second conductive features connected to the interconnecting layer 622 may be formed in the subsequent steps.

In some embodiments, after bonding the bottom die 620 to the backside RDL 410, the top die 430 is stacked on the bottom die 620. For example, the conductive bumps 434 of the top die 430 are aligned with and bonded to the first conductive features 625 of the bottom die 620 through the conductive bonding layer SJ. An insulating encapsulation 640 with a plurality of through holes TH′ is formed on the first surface 410a of the backside RDL 410 to encapsulate the top and bottom dies 430 and 520 and the TIVs 650. Subsequently, a plurality of second conductive features 628 is formed in the through holes TH′ of the insulating encapsulation 640 to be electrically connected to the interconnecting layer 624. The top die 430 may be similar to the top die shown in FIG. 5B, and the details thereof are omitted for brevity. The top die 430 may be disposed corresponding to the central region of the front surface 621a of the semiconductor substrate 621. After stacking the top die 430, the insulating encapsulation 640 with the through holes TH′ may be formed on the backside RDL 410. The through holes TH′ may be formed corresponding to the peripheral region of the front surface 621a of the semiconductor substrate 621. The forming method of the through holes TH′ may be similar to that of the through holes TH′ described in FIG. 6B. The through holes TH′ may expose at least a portion of the circuitry (not shown) of the interconnecting layer 622 for further electrical connection.

After forming the insulating encapsulation 640 with the through holes TH′, the second conductive features 628 may be formed in the through holes TH′ to be electrically connected to the interconnecting layer 524. The second conductive features 628 may be tapered toward the front surface 621a of the semiconductor substrate 621. Other shapes and forms of the second conductive features may be possible. A planarization process is optionally performed. In some embodiments, the top surface 640a of the insulating encapsulation 640 is substantially coplanar with the top surfaces 650a of the TIVs 650, the top surfaces 628a of the second conductive features 628. In some other embodiments, the top surface 640a of the insulating encapsulation 640 may also be substantially coplanar with the back side 430b of the top die 430.

Referring to FIG. 7B, the front side RDL 460 including the patterned dielectric layer 462 and the patterned conductive layer 464 is formed on the insulating encapsulation 640, the die stack DS6, and the TIVs 650. The patterned conductive layer 464 may be physically and electrically connected to the TIVs 650 and the second conductive features 628. After forming the front side RDL 460, the front side conductive terminals 470 are formed on the front side RDL 460 so that the die stack DS6 is electrically coupled to the front side conductive terminals 470 through the front side RDL 460. The forming process of the front side RDL 460 and the front side conductive terminals 470 may be similar to those of the front side RDL 460 and the front side conductive terminals 470 described in FIG. 5C and FIG. 1G, so the details thereof are omitted for brevity. Subsequently, the temporary carrier 50 is removed to expose the second surface 410b of the backside RDL 410. The removing process of the temporary carrier 50 may be similar to that of the temporary carrier 50 described in FIG. 1G, so the details thereof are omitted for brevity. After removing the temporary carrier 50, the patterned conductive layer 412 on the second surface 410b may be exposed for further electrical connection.

Referring to FIG. 7C, the backside conductive terminals 480 is formed on the second surface 410b of the backside RDL 410 to be connected to the patterned conductive layer 412. The backside conductive terminals 480 may be electrically coupled to the die stack DS4 through the backside RDL 410. The forming process and the material of the backside conductive terminals 480 may be similar to those of the backside conductive terminals 480 described in FIG. 5D. A singulation process may be performed and the manufacturing process of a semiconductor package SP6 is substantially completed.

The semiconductor package SP6 includes the die stack DS6, the insulating encapsulation 640 encapsulating the die stack DS6, the front side RDL 460 and the backside RDL 410 disposed on two opposite sides of the insulating encapsulation 640, and the TIVs 650 disposed aside the die stack DS6 and extending through the insulating encapsulation 640 to be electrically connected to the front side RDL 460 and the backside RDL 410. The die stack DS6 includes the bottom die 620 and the top die 430 stacked upon one another and electrically connected to the bottom die 620. The bottom die 620 includes the TSVs 623 disposed therein, and the first and second conductive features 625 and 628 having different thicknesses. The backside RDL 410 is connected to the TSVs 623 of the bottom die 620. The first conductive features 625 may be connected to the top die 430, the second conductive features 628 may be disposed aside the first conductive features 625 and connected to the front side RDL 460, where the second conductive features 628 may be thicker than the first conductive features 625. Each of TSVs 623 of the bottom die 620 has two opposing ends, and one end of each TSV 623 is connected to the backside RDL 410 through the conductive contacts 624, and the other end of the TSV 623 is connected to the interconnecting layer 622 and faces toward the first and second conductive feature 625 and 628. The second conductive feature 628 may be tapered in a direction from the front side RDL 460 toward the backside RDL 410. The underfill layer UF (illustrated in FIG. 7A) may be disposed between the bottom die 620 and the backside RDL 410.

Based on the above, the semiconductor package including the die stack structure may provide multi-functions in a single package to reduce the fabrication cost and the packaging volume. Moreover, since the first die and the second die are connected to each other through the TSVs, the signal transmission path between the first and second dies is shortened to improve the efficiency. The integration of the semiconductor package may be greatly enhanced. Multiple device component(s) may be disposed on and electrically connected to the front side conductive terminals and/or the backside conductive terminals to provide additional functionality. The TIVs are connected to the front side RDL and the backside RDL so as to provide the signal transmission path between the die stack and other device component(s) disposed on the front side conductive terminals and/or the backside conductive terminals. The TIVs are formed inside the through holes of the insulating encapsulation, and the through holes may be formed by laser drilling for saving the manufacturing cost.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A semiconductor package, comprising:
a die stack, comprising a first die and a second die stacked upon one another and electrically connected to the first die, the second die comprising a through semiconductor via (TSV) disposed therein, wherein one of the first die and the second die comprises conductive features having different thicknesses;
an insulating encapsulation, encapsulating the die stack;
a first redistribution layer (RDL) and a second RDL disposed on two opposite sides of the insulating encapsulation, wherein the second RDL is connected to the TSV of the second die; and
a through insulating via (TIV), disposed aside the die stack and extending through the insulating encapsulation to be electrically connected to the first RDL and the second RDL.

2. The semiconductor package of claim 1, wherein the first die of the die stack comprises:
a first conductive feature, connected to the second die; and
a second conductive feature, disposed aside the first conductive feature and connected to the second RDL, and being thicker than the first conductive feature.

3. The semiconductor package of claim 2, wherein the TSV of the second die comprises two opposing ends respectively connected to the first conductive feature and the second RDL.

4. The semiconductor package of claim 2, wherein the TIV is tapered in a direction toward the first RDL or the second RDL.

5. The semiconductor package of claim 2, wherein the second conductive feature of the first die is tapered in a direction from the second RDL toward the first RDL.

6. The semiconductor package of claim 1, wherein the second die of the die stack comprises:
a first conductive feature, connected to the first die; and
a second conductive feature, disposed aside the first conductive feature and connected to the first RDL, the second conductive feature being thicker than the first conductive feature.

7. The semiconductor package of claim 6, wherein the TSV of the second die comprises a first end facing toward the first conductive feature and the second conductive feature, and a second end connected to the second RDL.

8. The semiconductor package of claim 6, wherein the second conductive feature of the second die is tapered in a direction from the first RDL toward the second RDL.

9. The semiconductor package of claim 6, wherein the TIV is tapered in a direction from the first RDL toward the second RDL.

10. The semiconductor package of claim 1, wherein a thickness of the TIV is greater than a thickness of the die stack.

11. The semiconductor package of claim 1, further comprising:
an underfill, disposed between the second die of the die stack and the second RDL.

12. A manufacturing method of a semiconductor package, comprising:
disposing a die stack on a first redistribution layer (RDL), wherein the die stack comprises a first die and a second die stacked upon one another, the second die comprises a through semiconductor via (TSV) disposed therein, wherein one of the first die and the second die comprises conductive features having different thicknesses;
forming an insulating encapsulation on the first RDL to encapsulate the die stack;
forming a through insulating via (TIV) on the first RDL, wherein the TIV is laterally encapsulated by the insulating encapsulation; and
forming a second RDL on the insulating encapsulation to be connected to the TIV and the TSV of the second die of the die stack.

13. The manufacturing method of claim 12, wherein disposing the die stack on the first RDL comprises:
disposing the first die on the first RDL, wherein the first die comprises a first conductive feature and a second conductive feature disposed aside the first conductive feature, and the second conductive feature is thicker than the first conductive feature; and
connecting the TSV of the second die to the first conductive feature of the first die, wherein after forming the second RDL, the TSV of the second die and the second conductive feature of the first die are connected to the second RDL.

14. The manufacturing method of claim 12, wherein forming the insulating encapsulation and forming the TIV comprise:
forming an insulating material on the first RDL to encapsulate the die stack;
removing a portion of the insulating material to form the insulating encapsulation with a tapered through hole, wherein the tapered through hole is formed aside the die stack and exposes at least a portion of the first RDL; and
forming a conductive material in the tapered through hole to form the TIV.

15. The manufacturing method of claim 12, wherein first die comprises a first conductive feature and a second conductive feature disposed aside the first conductive feature, the second conductive feature is thicker than the first conductive feature, and disposing the die stack on the first RDL comprises:
bonding an end of the TSV of the second die to the first RDL; and
bonding the first conductive feature of the first die to an opposing end of the TSV of the second die and bonding the second conductive feature of the first die to the first RDL.

16. The manufacturing method of claim 12, wherein the second die of the die stack comprises a first conductive feature and a second conductive feature disposed aside the first conductive feature, the second conductive feature is thicker than the first conductive feature, and disposing the die stack on the first RDL comprises:
disposing the second die on the first RDL so that the TSV of the second die is connected to the first RDL; and
connecting the first die to the first conductive feature of the second die, wherein after forming the second RDL, the second conductive feature is connected to the second RDL.

17. The manufacturing method of claim 16, wherein disposing the die stack on the first RDL further comprises:
forming an underfill between the second die and the first RDL to laterally encapsulate the TSV of the second die after disposing the second die on the first RDL.

18. The manufacturing method of claim 12, wherein forming the TIV on the first RDL is prior to disposing the die stack on the first RDL.

19. The manufacturing method of claim 18, wherein forming the insulating encapsulation comprises:
forming an insulating material on the first RDL to encapsulate the TIV, the first die, and the second die, wherein the first die is connected to the first RDL, and the second die is stacked on the first die;
removing a portion of the insulating material to form the insulating encapsulation with a tapered through hole, wherein the tapered through hole is formed aside the second die and exposes at least a portion of the first die; and
forming a conductive material in the tapered through hole to connect the first die.

20. The manufacturing method of claim 18, wherein forming the insulating encapsulation comprises:
forming an insulating material on the first RDL to encapsulate the TIV, the first die, and the second die, wherein the second die is connected to the first RDL, and the first die is stacked on the second die;
removing a portion of the insulating material to form the insulating encapsulation with a tapered through hole, wherein the tapered through hole is formed aside the first die and exposes at least a portion of the second die; and
forming a conductive material in the tapered through hole to be in contact with the second die.
